(19) United States
(12) Patent Application Publication
(10) Pub. No.: US 2026/0319376 A1
(43) Pub. Date: Oct. 15, 2026

(54) Systems, Methods, And Devices For Full-Sized Pellicle Imaging

(71) Applicant: EUV Tech, Inc., Martinez, CA (US)

(72) Inventor: Patrick Naulleau, Pleasant Hill, CA (US)

(21) Appl. No.: 19/174,568

(22) Filed: Apr. 9, 2025

(51) Int. Cl. G03F 7/00; G03F 1/62

(52) U.S. Cl. CPC G03F 7/70316; G03F 1/62; G03F 7/70033

(57) ABSTRACT

Systems, methods, and devices disclosed herein image pellicles in various operational environments. Systems include a light source configured to generate a first optical output, an optical device configured to receive the first optical output, and further configured to generate a second optical output based, at least in part, on the first optical output, and an imaging device configured to generate an image based on the second optical output received after the second optical output has been provided to a target pellicle. Moreover, the second optical output includes a converging beam having a first cross-sectional area larger than the target pellicle, and also having a second cross-sectional area smaller than a sensor of the imaging device.

### FIELD OF TECHNOLOGY

This patent application relates generally to pellicle imaging, and more specifically to extreme ultraviolet (EUV) pellicle imaging.

### BACKGROUND

Pellicle films may be used in the context of various types of lithography. For example, pellicles may be used in a semiconductor manufacturing process, and may be used as a protective element used in combination with one or more other components, such as a photomask. Such pellicles may be implemented using a pellicle frame, and may be configured to have transmissive qualities that allow the passage of light. Conventional techniques for measuring such transmissive characteristics of pellicles remain limited because they are not able to efficiently provide imaging of the entire pellicle at the same time, thus resulting in reduced speed and accuracy of imaging.

### SUMMARY

In some embodiments, techniques described herein relate to a system for pellicle imaging. Systems include a light source configured to generate a first optical output, an optical device configured to receive the first optical output, and further configured to generate a second optical output based, at least in part, on the first optical output, and an imaging device configured to generate an image based on the second optical output received after the second optical output has been provided to a target pellicle. Moreover, the second optical output includes a converging beam having a first cross-sectional area larger than the target pellicle, and also having a second cross-sectional area smaller than a sensor of the imaging device.

In various embodiments, the optical device includes a collector mirror. In some embodiments, the collector mirror is configured to generate the second optical output based, at least in part, on a reflection of the first optical output. According to some embodiments, the converging beam is configured to encompass the target pellicle when it is provided to the target pellicle such that the entire target pellicle is exposed to the second optical output. In various embodiments, collector mirror comprises an aspherical mirror that is off-axis relative to the light source. In some embodiments, the light source is an extreme ultraviolet (EUV) light source configured to generate an EUV laser output. According to some embodiments, the systems further include an optical shutter. In various embodiments, the optical shutter is positioned between the light source and the optical device. In some embodiments, the optical shutter is positioned between the optical device and the imaging sensor.

Devices include an extreme ultraviolet (EUV) light source configured to generate a first optical output comprising EUV light, an optical assembly configured to receive the first optical output, the optical assembly comprising a collector mirror configured to generate a second optical output based, at least in part, on the first optical output, and an imaging sensor configured to generate an image based on the second optical output received after the second optical output has been provided to a target pellicle. Moreover, the second optical output comprises a converging beam having a first cross-sectional area larger than the target pellicle, and also having a second cross-sectional area smaller than the imaging sensor.

In various embodiments, the collector mirror is configured to generate the second optical output based, at least in part, on a reflection of the first optical output. In some embodiments, the converging beam is configured to encompass the target pellicle when it is provided to the target pellicle such that the entire target pellicle is exposed to the second optical output. According to some embodiments, devices further include an optical shutter. In some embodiments, the optical shutter is positioned between the light source and the optical assembly. According to some embodiments, the optical shutter is positioned between the optical assembly and the imaging sensor. Devices may further include a condenser mirror positioned between the collector mirror and the target pellicle.

Methods are disclosed herein that include receiving a first optical output from a light source, generating, using an optical device, a second optical output based on the first optical output, providing the second optical output to a target pellicle, and receiving the second optical output at an imaging device after the second optical output has been provided to the target pellicle. Moreover, the second optical output comprises a converging beam having a first cross-sectional area larger than the target pellicle, and also having a second cross-sectional area smaller than a sensor of the imaging device.

In various embodiments, the optical device includes a collector mirror, and wherein the second optical output is generated using the collector mirror and based, at least in part, on a reflection of the first optical output. In some embodiments, the converging beam encompasses the target pellicle when it is provided to the target pellicle such that the entire target pellicle is exposed to the second optical output. According to some embodiments, methods further include providing the second optical output to an optical shutter after being provided to the target pellicle, activating the optical shutter, and providing the second optical output to the imaging sensor.

These and other embodiments are described further below with reference to the figures.

### BRIEF DESCRIPTION OF THE DRAWINGS

The included drawings are for illustrative purposes and serve only to provide examples of possible structures and operations for the disclosed inventive systems, apparatus, methods, and devices for pellicle imaging. These drawings in no way limit any changes in form and detail that may be made by one skilled in the art without departing from the spirit and scope of the disclosed implementations.

FIG. 1 illustrates an example of a system for pellicle imaging, configured in accordance with some embodiments.

FIG. 2 illustrates an example of a device for pellicle imaging, configured in accordance with some embodiments.

FIG. 3 illustrates another example of a device for pellicle imaging, configured in accordance with some embodiments.

FIG. 4 illustrates an additional example of a device for pellicle imaging, configured in accordance with some embodiments.

FIG. 5 illustrates another example of a device for pellicle imaging, configured in accordance with some embodiments.

FIG. 6 illustrates an additional example of a device for pellicle imaging, configured in accordance with some embodiments.

FIG. 7 illustrates another example of a device for pellicle imaging, configured in accordance with some embodiments.

FIG. 8 illustrates an example of a method for pellicle imaging, performed in accordance with some embodiments.

FIG. 9 illustrates another example of a method for pellicle imaging, performed in accordance with some embodiments.

FIG. 10 illustrates an additional example of a method for pellicle imaging, performed in accordance with some embodiments.

### DETAILED DESCRIPTION

Pellicles may be used in extreme ultraviolet (EUV) lithography processes to protect a lithography mask from ambient particles that may otherwise fall on and contact the mask. Such pellicles are designed to be uniform in both EUV transmittance and reflectance over the full area of the pellicle which, in some examples, may be 140 mm in diameter. While such uniformity is desired, it will be appreciated that some variances and deviations in uniformity may sometimes be present. Accordingly, measurement of pellicle uniformity is used to determine if a pellicle is suitable for use in a lithography process.

Conventional techniques for measuring pellicle uniformity remain limited because they rely on the use of scanning a pellicle with a small beam, thus obtaining multiple images for a single pellicle, and introducing additional variability based on variances in the imaging equipment and process itself. Such techniques are not suitable for relatively larger pellicles and rely on time-multiplexed image stitching, thus further reducing measurement uniformity.

Embodiments disclosed herein provide large area pellicle measurement by decoupling measurement uniformity limits from light source temporal characteristics while simultaneously supporting high speed measurements of a total pellicle. As will be discussed in greater detail below, a light source, which may be an EUV light source, may generate light provided to an optical assembly that provides a designated amount of demagnification during a pellicle illumination and imaging process. In one example, a demagnifying shadow cast projection system enables a full-sized pellicle map to be projected onto a smaller format imaging sensor. In this way, full imaging of the pellicle may be achieved even if the imaging sensor is smaller than the pellicle being imaged. Because the full pellicle is captured per image, measurement uniformity is improved.

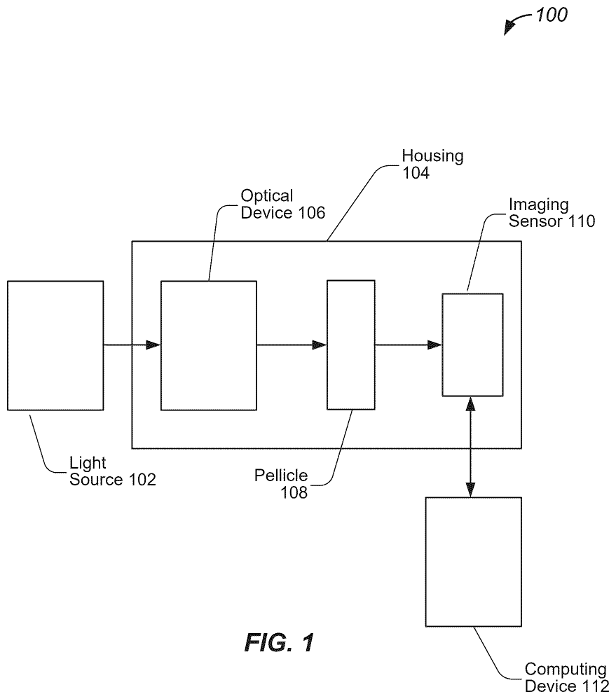

FIG. 1 illustrates an example of a system for pellicle imaging, configured in accordance with some embodiments. As will be discussed in greater detail below, embodiments disclosed herein improve large area pellicle measurement uniformity by decoupling measurement uniformity constraints from the light source temporal characteristics, while also simultaneously supporting high speed measurements of the full pellicle. Accordingly, a system, such as system 100, may be configured to implement a projection system enabling a full-sized pellicle map to be projected onto an imaging sensor, thus enabling imaging of the pellicle in one capture.

In various embodiments, system 100 includes a light source, such as light source 102, which is configured to generate light used for pellicle imaging operations described herein. In various embodiments, light source 102 is configured to generate EUV light. Accordingly, light source 102 may be configured to generate EUV light based on the generation of a laser produced plasma. In some embodiments, light source 102 is configured to generate EUV light based on the generation of discharge produced plasma. It will be appreciated that any suitable technique for generating EUV light is contemplated and disclosed herein. Moreover, while various embodiments describe the use of EUV light, any suitable wavelengths of light may be used for pellicle imaging. For example, shorter wavelengths, such as soft-x-ray wavelengths may be used. It will be appreciated that the wavelength range may be selected to match the wavelength range used in associated lithography operations.

System 100 additionally includes optical device 106 which is configured to receive light from light source 102, and further configured to project the received light onto a target pellicle, such as pellicle 108. As will be discussed in greater detail below, optical device 106 is configured to include one or more optical elements configured to change a cross-sectional area of light generated by light source 102 from a first cross-sectional area to a second cross-sectional area. More specifically, light source 102 may generate a beam of light having the first cross-sectional area that is smaller than pellicle 108 and also imaging sensor 110 discussed in greater detail below. Optical device 106 includes one or more optical elements configured to change the first cross-sectional area to a second cross-sectional area that is larger than pellicle 108 when passing pellicle 108.

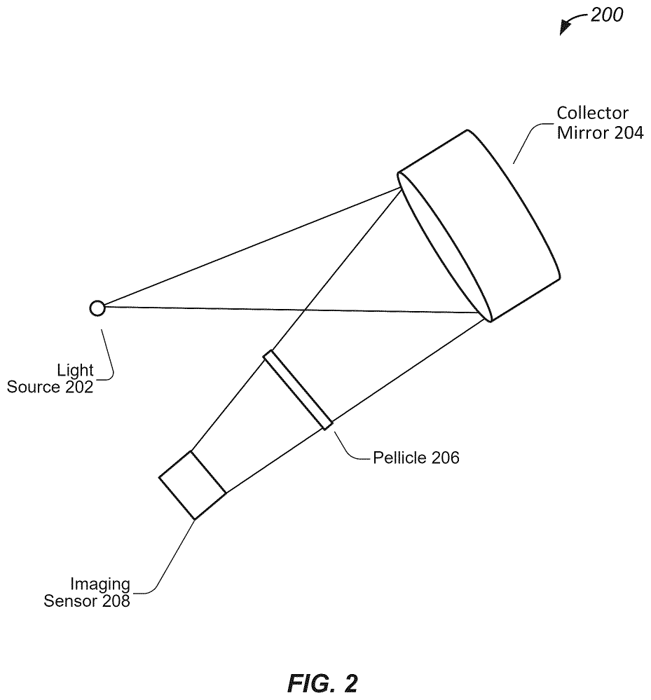

In some embodiments, optical device 106 may be further configured to also apply an amount of convergence such that the cross sectional area of the output of optical device 106 has a diameter large enough to encompass pellicle 108 when passing pellicle 108, and also has a diameter small enough to be smaller than imaging sensor 110 when arriving at imaging sensor 110, and while pellicle 108 is larger than imaging sensor 110. In this way, a configuration of optical elements within optical device 106 may be configured specifically based on a size of pellicle 108 and a size of imaging sensor 110 as well as their distances from optical device 106. Such specifically configured convergence provides improved luminosity of the imaging light by reducing excessive beam spread to areas not otherwise used by imaging sensor 110. Moreover, such convergence provides demagnification of the image that allows imaging of the entirety of pellicle 108 even if pellicle 108 is larger than imaging sensor 110. In one example, optical device 106 may include one or more optical elements configured to implement a geometric demagnifying shadow cast projection system that is configured to implement such convergence. Additional details regarding these features are discussed in greater detail below with reference to at least FIG. 2.

System 100 further includes imaging sensor 110 which is configured to capture images of pellicle 108 based on the light provided by optical device 106. Accordingly, light may be provided from optical device 106 to pellicle 108, and imaging sensor 110 may capture an image of pellicle 108 that is backlit by the light provided by optical device 106. In various embodiments, imaging sensor 110 is a charge-coupled device (CCD) camera or a complementary metal-oxide-semiconductor (CMOS) camera. It will be appreciated that any suitable imaging device may be used. As shown in FIG. 1, optical device 106, pellicle 108 and imaging sensor 110 may be included in housing 104 that is configured to provide structural support for positioning of elements of each of optical device 106, pellicle 108 and imaging sensor 110.

In various embodiments, imaging sensor 110 may capture the image as a digital file that is provided to computing device 112 via a communications interface. Accordingly, computing device 112 may be a computer or other computing system that includes one or more processors and memory configured to communicate with imaging sensor 110 and receive imaging data from imaging sensor 110 where such imaging data includes the captured image of pellicle 108. Moreover, computing device 112 may also be configured to provide data to imaging sensor 110, such as one or more data values configured to implement exposure parameters such as sensitivity and time settings.

FIG. 2 illustrates an example of a device for pellicle imaging, configured in accordance with some embodiments. As similarly discussed above, embodiments disclosed herein provide large area pellicle measurement while also providing high speed measurements of the full pellicle. Accordingly, a device, such as device 200, may be configured to implement projection optics configured to enable a full-sized pellicle map to be projected onto an imaging sensor, thus enabling imaging of the pellicle in a single image capture and avoiding the use of scanning operations.

In various embodiments, device 200 includes light source 202. As similarly discussed above, light source 202 is configured to generate light used for pellicle imaging operations described herein. For example, light source 202 is configured to generate EUV light in any suitable manner. As also discussed above, while various embodiments describe the use of EUV light, any suitable wavelengths of light may be used for pellicle imaging.

As shown in FIG. 2, light generated by light source 202 is provided to collector mirror 204. In some embodiments, collector mirror 204 is an off-axis mirror configured to create a converging beam that is larger than a target pellicle, such as pellicle 206, as it passes through pellicle 206. In various embodiments, collector mirror 204 includes a reflective element that is coated in an EUV reflective material. Moreover, collector mirror 204 is configured to have an aspheric geometry configured to generate a designated amount of beam convergence. Accordingly, the converging beam generated by collector mirror 204 then converges at imaging sensor 208 such that the beam size at imaging sensor 208 is smaller than the active sensor area of imaging sensor 208. In this way, a geometric demagnifying mapping is established between localized areas on pellicle 206 and pixels of imaging sensor 208. Moreover, the entire area of pellicle 206 can be projected onto imaging sensor 208 and within an active sensor area of imaging sensor 208. In various embodiments, the size of such active sensor area is smaller than the size of pellicle 206. In this way a full image of pellicle 206 may be generated in a single capture, and demagnification may be provided to compensate for a smaller size of imaging sensor 208 relative to pellicle 206. In various embodiments, the demagnification may have a demagnification ratio that is at least as large as the ratio a size of pellicle 206 to a size of the imaging sensor.

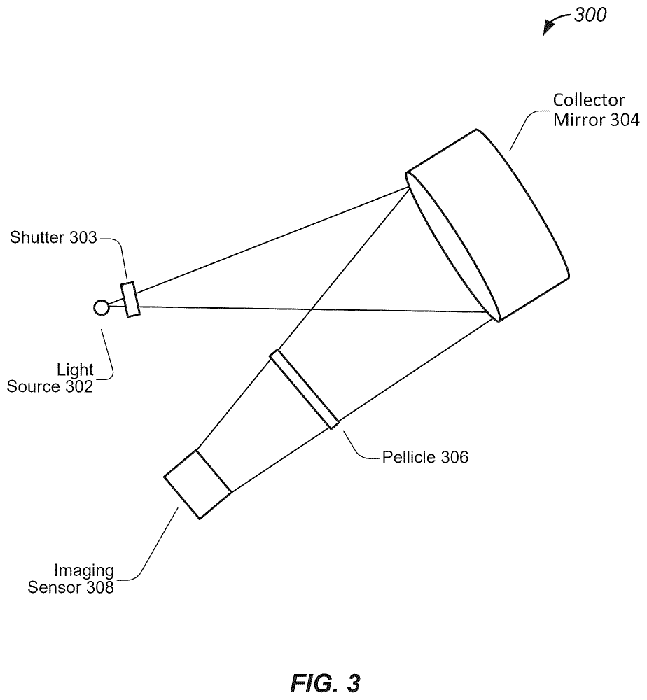

FIG. 3 illustrates another example of a device for pellicle imaging, configured in accordance with some embodiments. As similarly discussed above, embodiments disclosed herein provide large area pellicle measurement while also providing high speed measurements of the full pellicle. Accordingly, a device, such as device 300, may be configured to implement projection optics configured to enable a full-sized pellicle map to be projected onto an imaging sensor, thus enabling imaging of the pellicle in a single image capture and avoiding the use of scanning operations. Moreover, as will be discussed in greater detail below, device 300 may include a shutter configured to provide optical gating for the imaging sensor.

As similarly discussed above, device 300 may include light source 302 that is configured to generate light used for pellicle imaging operations described herein. For example, light source 302 is configured to generate EUV light in any suitable manner. Moreover, device 300 further includes collector mirror 304 that may be an off-axis mirror configured to create a converging beam that is larger than a target pellicle, such as pellicle 306, as it passes through pellicle 306. As similarly discussed above, the converging beam generated by collector mirror 304 then converges at imaging sensor 308 such that the beam size at imaging sensor 308 is smaller than the active sensor area of imaging sensor 308.

In various embodiments, device 300 additionally includes shutter 303 which is configured to provide optical gating for light source 302. As shown in FIG. 3, shutter 303 is positioned at an output of light source 302 and is configured to block light generated by light source 302 when closed. Accordingly, during imaging operations when an exposure is being made and an image is being captured, shutter 303 may be opened and may allow light to pass from light source 302 to collector mirror 304, as well as downstream components of pellicle 306 and imaging sensor 308. Operation of shutter 303 may be controlled by a computing device, as discussed above. In this way, shutter 303 provides protection of other components within device 300 by reducing their exposure to EUV light when no image is being captured and avoiding the need to turn light source 302 on and off for such purposes. Additionally, shutter 303 is configured to control the total exposure level experience by sensor 308 thus ensuring that sensor 308 is not saturated during imaging operations.

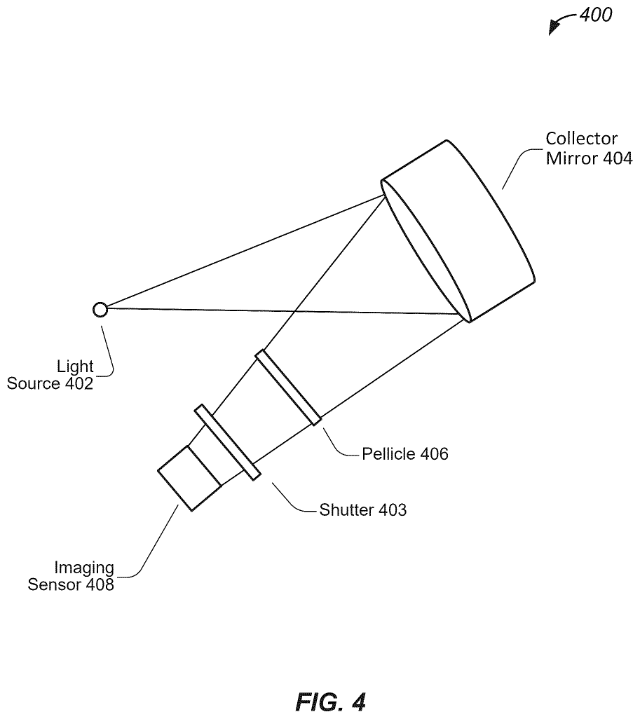

FIG. 4 illustrates an additional example of a device for pellicle imaging, configured in accordance with some embodiments. As similarly discussed above, embodiments disclosed herein provide large area and high-speed measurements of a full pellicle. Accordingly, a device, such as device 400, may be configured to implement projection optics configured to enable a full-sized pellicle map to be projected onto an imaging sensor. Moreover, as will be discussed in greater detail below, device 400 may include a shutter configured to provide optical gating for the imaging sensor.

As similarly discussed above, device 400 may include light source 402 that is configured to generate light used for pellicle imaging operations described herein. Moreover, device 400 further includes collector mirror 404 that may be an off-axis mirror configured to create a converging beam that is larger than a target pellicle, such as pellicle 406, as it passes through pellicle 406. As similarly discussed above, the converging beam generated by collector mirror 404 then converges at imaging sensor 408 such that the beam size at imaging sensor 408 is smaller than the active sensor area of imaging sensor 408.

In various embodiments, device 400 additionally includes shutter 403 which is configured to provide optical gating for light generated by light source 402. As shown in FIG. 4, shutter 403 is positioned between pellicle 406 and imaging sensor 408, and thus gates the optical input received by imaging sensor 408. Accordingly, during imaging operations when an exposure is being made and an image is being captured, shutter 403 may be opened and may allow light to pass from pellicle 406 to imaging sensor 408. In this way, shutter 403 is used to control the exposure level on imaging sensor 408 during the imaging process and provides additional protection of imaging sensor 408 by reducing its exposure to EUV light when no image is being captured. Moreover, when positioned between pellicle 406 and imaging sensor 408, shutter 403 may experience less intense exposure to light generated by light source 402 and may experience relatively increased longevity depending on a design and construction of shutter 403.

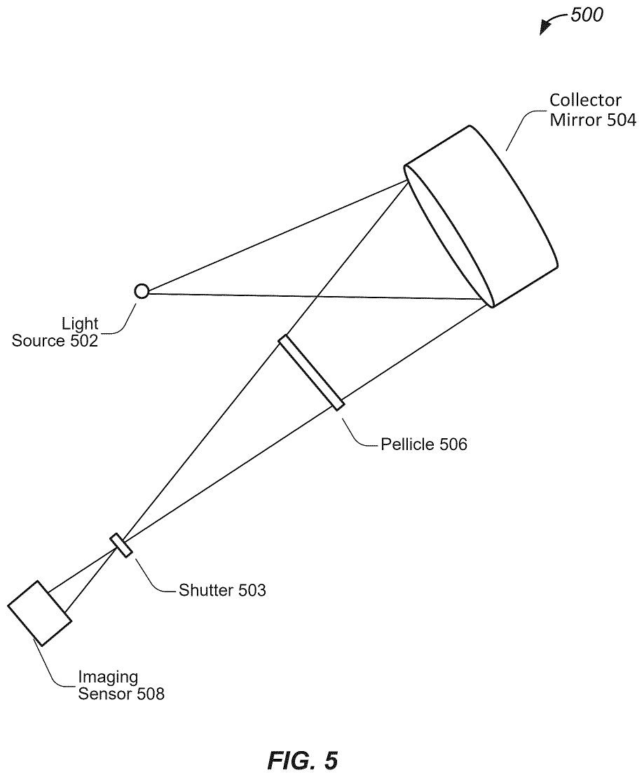

FIG. 5 illustrates another example of a device for pellicle imaging, configured in accordance with some embodiments. As similarly discussed above, a device, such as device 500, may be configured to implement projection optics configured to enable a full-sized pellicle map to be projected onto an imaging sensor. Moreover, as also discussed above, a shutter may be placed between an imaging sensor and a pellicle being imaged. As will be discussed in greater detail below, device 500 may be configured such that the placement of the shutter relative to other components of device 500 is configured to reduce a size of the shutter, thus allowing faster operational speeds and increased beam uniformity.

Accordingly, device 500 may include light source 502, collector mirror 504, pellicle 506, and imaging sensor 508. As similarly discussed above, light source 502 is configured to generate light, such as EUV light, that may be provided to collector mirror 504, which then provides projected light to pellicle 506, and ultimately to imaging sensor 508. As shown in FIG. 5, shutter 503 may be placed at the focal distance of collector mirror 504 at which point a cross-sectional area of the projected light may have converged and be relatively small. Moreover, imaging sensor 508 may be placed behind the focal distance, thus capturing an inverted image of pellicle 506 which may subsequently be re-oriented or otherwise processed in post processing performed on a computing device. By leveraging the relationship between beam size/cross-sectional area and distance from collector mirror 504, the size of shutter 503 may be reduced, thus allowing faster mechanical operation of shutter 503 itself as well as improving the exposure uniformity during the image acquisition process on imaging sensor 508.

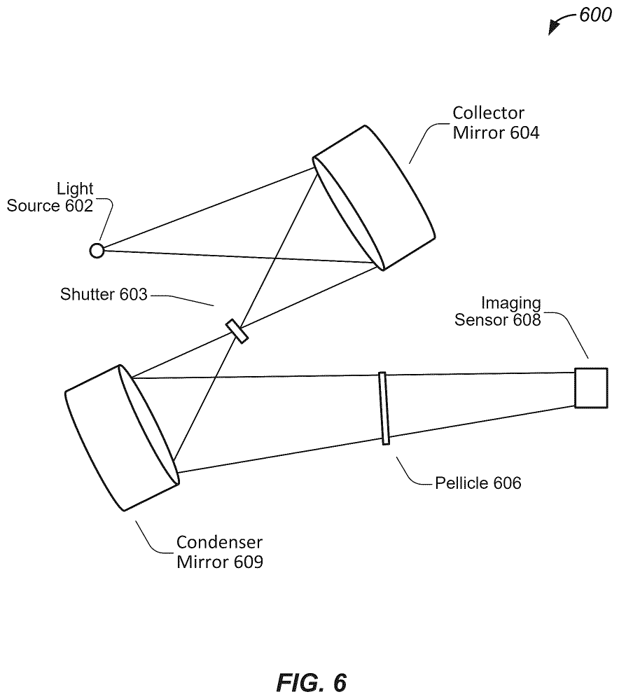

FIG. 6 illustrates an additional example of a device for pellicle imaging, configured in accordance with some embodiments. As similarly discussed above, a device, such as device 600, may be configured to implement projection optics configured to enable a full-sized pellicle map to be projected onto an imaging sensor. As also discussed above, a shutter may be placed at a focal distance of a collector mirror. As will be discussed in greater detail below, device 600 may be configured to include additional optical elements to improve a resolution of imaging provided by device 600.

Accordingly, device 600 may include light source 602, collector mirror 604, shutter 603, pellicle 606, and imaging sensor 608. As similarly discussed above, light source 602 is configured to generate light, such as EUV light, that may be provided to collector mirror 604, which then provides projected light to shutter 603, and ultimately to pellicle 606 and imaging sensor 608. Moreover, shutter 603 may be placed at the focal distance of collector mirror 604.

In various embodiments, device 600 additionally includes condenser mirror 609 which is configured to receive light from collector mirror 604 after the focal distance of collector mirror 604, and at which point the beam is divergent. Condenser mirror 609 may converge such light and provide it to pellicle 606 and imaging sensor 608 to provide total coverage of pellicle 606 and a converged image smaller than an active sensor area of imaging sensor 608, as similarly discussed above. In various embodiments, the geometries and curvatures of optical elements of collector mirror 604 and condenser mirror 609 are configured to reduce an overall distance of an optical path for light generated by light source 602 and received at imaging sensor 608. Such a reduced optical path provides improved imaging resolution and improved beam uniformity, thus improving the image captured by imaging sensor 608. As similarly discussed above, the convergence provided by condenser mirror 609 may provide demagnification for the image received at imaging sensor 608 that has a demagnification ratio that is at least as large as the ratio a size of pellicle 606 to a size of imaging sensor 608.

Moreover, in some embodiments, shutter 603 may be integrated with a barrier or wall within a housing that compartmentalizes light source 602 and collector mirror 604 from condenser mirror 609, pellicle 606, and imaging sensor 608. When configured in this way, additional protection may be provided for elements such as condenser mirror 609, pellicle 606, and imaging sensor 608 as they may be implemented in a separate chamber from light source 602, and may thus be substantially isolated from light source 602 which may have an associated operational environment that is high-energy and can be destructive to more sensitive components.

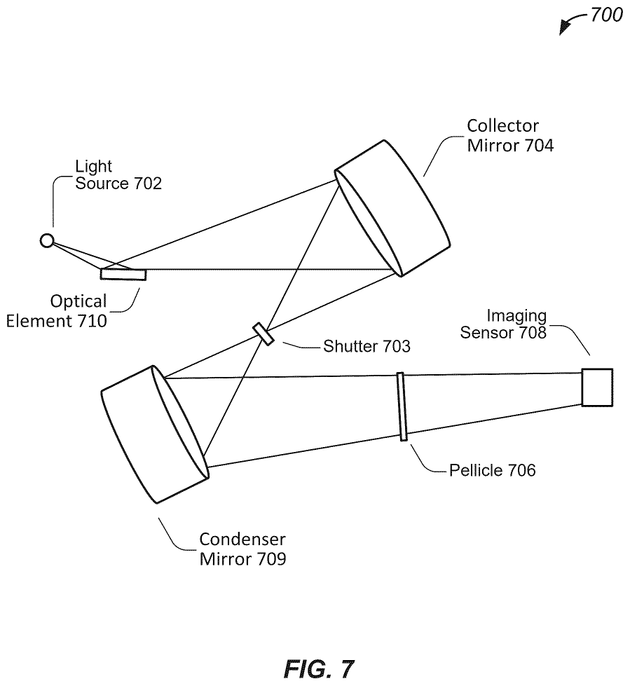

FIG. 7 illustrates another example of a device for pellicle imaging, configured in accordance with some embodiments. As similarly discussed above, a device, such as device 700, may be configured to implement projection optics configured to enable a full-sized pellicle map to be projected onto an imaging sensor. As also discussed above, a shutter may be placed at a focal distance of a collector mirror. As will be discussed in greater detail below, device 700 may be configured to include additional optical elements to provide additional protection for components of device 700.

Accordingly, device 700 may include light source 702, collector mirror 707, shutter 703, condenser mirror 709, pellicle 706, and imaging sensor 708. As similarly discussed above, light source 702 is configured to generate light, such as EUV light, that may ultimately be provided to collector mirror 704, which then provides projected light to shutter 703, condenser mirror 709, pellicle 706, and imaging sensor 708.

In various embodiments, device 700 additionally includes optical element 710 that may be configured as a glancing optic that may be ablative. Accordingly, light may be generated by light source 702 and may be provided to optical element 710 which may then reflect the light to collector mirror 704. In various embodiments, optical element 710 may be configured to absorb and/or filter one or more components of light generated by light source 702. Such filtered or absorbed components of the light, such as particular wavelengths and intensities of light, may otherwise be harmful to surfaces of components such as collector mirror 704 and condenser mirror 709. Accordingly, inclusion of optical element 710 at an output of light source 702 may reduce the presence of such harmful components in light provided to downstream components of device 700. In various embodiments, optical element 710 is ablative and may be replaced by an entity such as a user, administrator, or manufacturer. Moreover, one or more optical filters may be included in optical element 710, or may be implemented separately as an additional optical element. In this way, optical element 710 and associated optical elements may provide both filtration and mitigation of particular components of an output of light source 702.

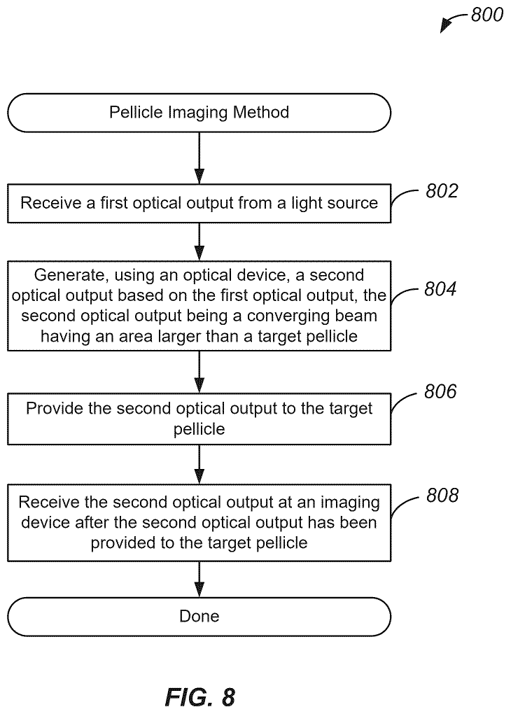

FIG. 8 illustrates an example of a method for pellicle imaging, performed in accordance with some embodiments. As similarly discussed above, embodiments disclosed herein improve large area pellicle measurement uniformity by decoupling measurement uniformity constraints from the light source temporal characteristics, while also simultaneously supporting high speed measurements of the full pellicle. Accordingly, a method, such as method 800, may be performed to facilitate a full-sized pellicle map being projected onto an imaging device, thus enabling imaging of the pellicle in one capture.

Method 800 may perform operation 802 during which a first optical output may be received from a light source. As similarly discussed above, an EUV light source may generate EUV light that is received at an optical device that is configured to receive the light, and generate a projection output. As also above, the light may be provided directly to the optical device, or one or more additional components may be placed between the light source and the optical device, such as a shutter or an ablative optic.

Method 800 may perform operation 804 during which a second optical output may be generated based on the first optical output. In various embodiments, the second optical output is a converging beam having an area larger than a target pellicle. Accordingly, as similarly discussed above, the second optical output may be a projection generated by the optical device based on the received first optical output. The optical device may generate the second optical output such that it has a first beam size and a first cross-sectional area that is greater than the target pellicle and provides full coverage of the target pellicle. Moreover, the optical device provides an amount of convergence to the second optical output such that the beam size and cross-sectional area reduce and converge a designated amount prior to being provided to the imaging device.

Method 800 may perform operation 806 during which the second optical output may be provided to the target pellicle. In various embodiments, the second optical output may cover the entire area of the target pellicle thus illuminating the entire target pellicle and enabling the entire target pellicle at once.

Method 800 may perform operation 808 during which the second optical output may be received at an imaging device after the second optical output has been provided to the target pellicle. In various embodiments, the second optical output may have converged by the designated amount such that it has a second beam size and a second cross-sectional area that is smaller than the target pellicle and smaller than an active sensor area of the imaging device. In this way, the imaging device may be provided with a full pellicle map of the target pellicle, and may capture an image of the full pellicle map in a single imaging operation. It will be appreciated that additional iterations of method 800 may be performed for additional imaging operations, as may be suitable in instances of image stacking or other imaging techniques.

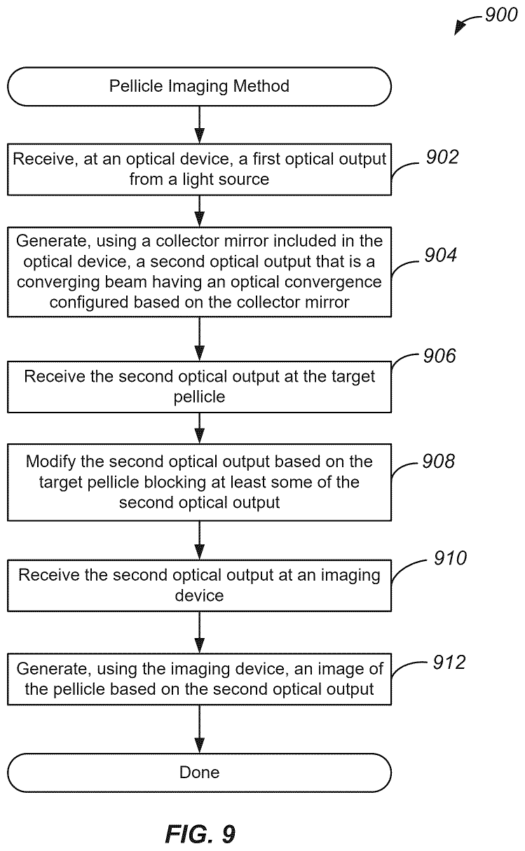

FIG. 9 illustrates another example of a method for pellicle imaging, performed in accordance with some embodiments. As similarly discussed above, embodiments disclosed herein facilitate a full-sized pellicle map being projected onto an imaging sensor, thus enabling imaging of the pellicle in one capture. As will be discussed in greater detail below, a method, such as method 900, may be performed to implement demagnification to provide such features when a size of the pellicle is larger than a size of a sensor of an imaging device.

Method 900 may perform operation 902 during which a first optical output may be received from a light source at an optical device. As similarly discussed above, an EUV light source may generate a first optical output that includes EUV light that is received at an optical device configured to generate a projection output. As also discussed above, the first optical output may be provided directly to the optical device, or one or more additional components may be placed between the light source and the optical device, such as a shutter or an ablative optic.

Method 900 may perform operation 904 during which a collector mirror included in the optical device may be used to generate a second optical output that is a converging beam having an optical convergence configured based on the collector mirror. As similarly discussed above, the optical device may include one or more optical elements, such as a collector mirror. The collector mirror may be configured to collect the first optical output received from the light source and generate a second optical output having a designated amount of convergence that provides demagnification of the projected image of the pellicle, while also still maintaining full coverage of the pellicle.

Method 900 may perform operation 906 during which the second optical output may be received at the target pellicle. Accordingly, the second optical output may be provided to the target pellicle and, as similarly discussed above, a first beam size of the second optical output may be larger than the target pellicle, thus providing full coverage of the target pellicle.

Method 900 may perform operation 908 during which the second optical output may be modified based on the target pellicle blocking at least some of the second optical output. Accordingly, light included in the second optical output may pass through the target pellicle, and transmissive parameters of the pellicle may affect the light that is passed through. Such transmissive parameters may be determined based on a shape of the target pellicle as well as uniformity and purity of the target pellicle. In this way, the modified second optical output includes a backlit image of the target pellicle generated based, at least in part, on the transmissive parameters of the target pellicle.

Method 900 may perform operation 910 during which the second optical output may be received at an imaging device. In various embodiments, the second optical output has a second beam size when reaching the imaging device. As similarly discussed above, the second beam size may be determined based, at least in part, on an amount of convergence provided by the collector mirror as it relates to sizes of the target pellicle and the imaging device. More specifically, the second beam size may have a cross-sectional area smaller than that of the first beam size, and smaller than an active sensor area of the imaging device. In this way, the full image of the pellicle may be demagnified and rendered within the active sensor area of the imaging device.

Method 900 may perform operation 912 during which an image of the pellicle may be generated based on the second optical output. Accordingly, the imaging device may perform imaging operations to capture an image of the pellicle. As similarly discussed above, the imaging device may include a CCD or CMOS sensor, and may generate pixel data representing the image of the pellicle. Such image may be provided to a computing device for subsequent analysis. Moreover, additional images may be captured for the purposes of image stacking and other post-processing operations such as noise reduction, contrast adjustments, and sharpening operations.

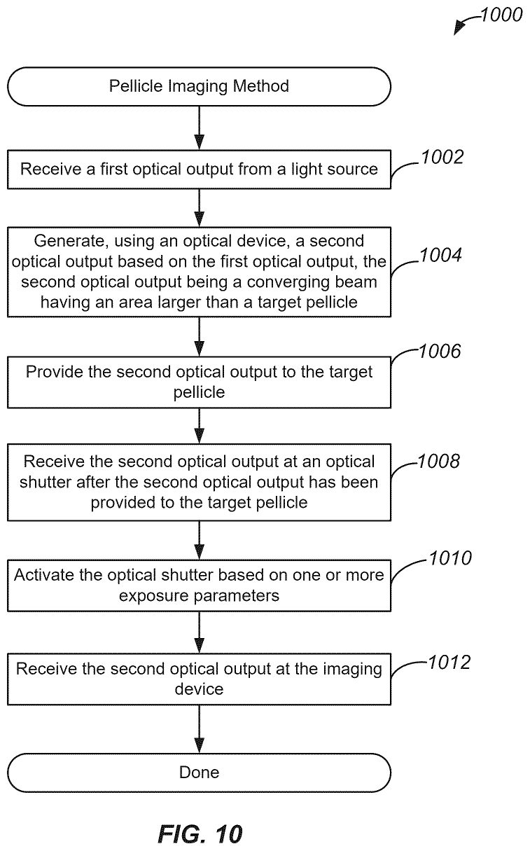

FIG. 10 illustrates an additional example of a method for pellicle imaging, performed in accordance with some embodiments. As similarly discussed above, embodiments disclosed herein facilitate a full-sized pellicle map being projected onto an imaging sensor, thus enabling imaging of the pellicle in one capture. As will be discussed in greater detail below, a method, such as method 1000, may be performed to control actuation of a shutter during implementation of imaging operations.

Method 1000 may perform operation 1002 during which a first optical output may be received from a light source. As similarly discussed above, an EUV light source may generate a first optical output that includes EUV light that is received at an optical device configured to generate a projection output. As also discussed above, the first optical output may be provided directly to the optical device, or one or more additional components may be placed between the light source and the optical device, such as an ablative optic.

Method 1000 may perform operation 1004 during which a second optical output may be generated based on the first optical output. In various embodiments, the second optical output is a converging beam having an area larger than a target pellicle. As similarly discussed above, the optical device may include one or more optical elements, such as a collector mirror. The collector mirror may be configured to collect the first optical output received from the light source and generate a second optical output having a designated amount of convergence that provides demagnification of the projected image of the pellicle, while also still maintaining full coverage of the pellicle.

Method 1000 may perform operation 1006 during which the second optical output may be provided to the target pellicle. Accordingly, the second optical output may be provided to the target pellicle and, as similarly discussed above, a first beam size of the second optical output may be larger than the target pellicle, thus providing full coverage of the target pellicle.

Method 1000 may perform operation 1008 during which the second optical output may be received at an optical shutter after the second optical output has been provided to the target pellicle. In one example, the shutter may be placed between the target pellicle and the imaging device. As similarly discussed above, the shutter may also be placed in other locations, such as between the light source and the collector mirror. In various embodiments, the shutter may be a mechanical shutter. For example, the shutter may be a curtain shutter or a full-frame shutter. It will be appreciated that any suitable shutter design may be used. Moreover, in some embodiments, a mechanical shutter is not used, and the imaging device is configured to implement an electronic shutter.

Method 1000 may perform operation 1010 during which the optical shutter may be activated based on one or more exposure parameters. In various embodiments, the shutter is configured to be actuated based on an input received from a computing device, and in accordance with one or more designated exposure parameters. Accordingly, the shutter may be configured to be closed as a default position, and may be triggered to open when an exposure is being made and in accordance with exposure parameters for a particular exposure. Such exposure parameters may designate an amount of time for which the shutter will remain open. Accordingly, during operation 1010, the shutter may open and allow the second optical output to pass through.

Method 1000 may perform operation 1012 during which the second optical output may be received at the imaging sensor. As similarly discussed above, the second optical output has a second beam size when reaching the imaging device. Moreover, the second beam size may have a cross-sectional area smaller than that of the first beam size, and smaller than an active sensor area of the imaging device. In this way, the full image of the pellicle may be demagnified and rendered within the active sensor area of the imaging device.

Accordingly, during operation 1012, the imaging device may perform imaging operations to capture an image of the target pellicle. Moreover, such imaging operations may be implemented in conjunction with the actuation of the shutter such that imaging operations are complete while the shutter is open. Such exposure parameters and imaging parameters may be determined and managed via a computing device and an application executed on the computing device in accordance with parameters specified by an entity, such as a manufacturer, user, or administrator.

Although the foregoing concepts have been described in some detail for purposes of clarity of understanding, it will be apparent that certain changes and modifications may be practiced within the scope of the appended claims. It should be noted that there are many alternative ways of implementing processes, systems, and apparatuses. Accordingly, the present embodiments are to be considered illustrative and not restrictive.

What is claimed is:

1. A system comprising:
a light source configured to generate a first optical output;
an optical device configured to receive the first optical output, and further configured to generate a second optical output based, at least in part, on the first optical output; and
an imaging device configured to generate an image based on the second optical output received after the second optical output has been provided to a target pellicle,
wherein the second optical output comprises a converging beam having a first cross-sectional area larger than the target pellicle, and also having a second cross-sectional area smaller than a sensor of the imaging device.

2. The system of claim 1, wherein the optical device comprises a collector mirror.

3. The system of claim 2, wherein the collector mirror is configured to generate the second optical output based, at least in part, on a reflection of the first optical output.

4. The system of claim 3, wherein the converging beam is configured to encompass the target pellicle when it is provided to the target pellicle such that the entire target pellicle is exposed to the second optical output.

5. The system of claim 3, wherein the collector mirror comprises an aspherical mirror that is off-axis relative to light source 202.

6. The system of claim 1, wherein the light source is an extreme ultraviolet (EUV) light source configured to generate an EUV laser output.

7. The system of claim 1 further comprising an optical shutter.

8. The system of claim 7, wherein the optical shutter is positioned between the light source and the optical device.

9. The system of claim 7, wherein the optical shutter is positioned between the optical device and the imaging sensor.

10. A device comprising:
an extreme ultraviolet (EUV) light source configured to generate a first optical output comprising EUV light;
an optical assembly configured to receive the first optical output, the optical assembly comprising a collector mirror configured to generate a second optical output based, at least in part, on the first optical output; and
an imaging sensor configured to generate an image based on the second optical output received after the second optical output has been provided to a target pellicle,
wherein the second optical output comprises a converging beam having a first cross-sectional area larger than the target pellicle, and also having a second cross-sectional area smaller than the imaging sensor.

11. The device of claim 10, wherein the collector mirror is configured to generate the second optical output based, at least in part, on a reflection of the first optical output.

12. The device of claim 10, wherein the converging beam is configured to encompass the target pellicle when it is provided to the target pellicle such that the entire target pellicle is exposed to the second optical output.

13. The device of claim 10 further comprising an optical shutter.

14. The device of claim 13, wherein the optical shutter is positioned between the light source and the optical assembly.

15. The device of claim 13, wherein the optical shutter is positioned between the optical assembly and the imaging sensor.

16. The device of claim 10 further comprising:
a condenser mirror positioned between the collector mirror and the target pellicle.

17. A method comprising:
receiving a first optical output from a light source;
generating, using an optical device, a second optical output based on the first optical output;
providing the second optical output to a target pellicle; and
receiving the second optical output at an imaging device after the second optical output has been provided to the target pellicle,
wherein the second optical output comprises a converging beam having a first cross-sectional area larger than the target pellicle, and also having a second cross-sectional area smaller than a sensor of the imaging device.

18. The method of claim 17, wherein the optical device comprises a collector mirror, and wherein the second optical output is generated using the collector mirror and based, at least in part, on a reflection of the first optical output.

19. The method of claim 18, wherein the converging beam encompasses the target pellicle when it is provided to the target pellicle such that the entire target pellicle is exposed to the second optical output.

20. The method of claim 17 further comprising:
providing the second optical output to an optical shutter after being provided to the target pellicle;
activating the optical shutter; and
providing the second optical output to the imaging sensor.
